(19) United States
(12) Patent Application Publication
(10) Pub. No.: US 2007/0152136 A1
(43) Pub. Date: Jul. 5, 2007

(54) Transimpedance amplifier protection circuits

(76) Inventors: Jianquo Yao, Didcot (GB); Qi Pan, Didcot (GB); Matthew Hagman, Ottawa (CA)

Correspondence Address: MARK D. SARALINO (GENERAL);RENNER, OTTO, BOISSELLE & SKLAR, LLP, 1621 EUCLID AVENUE, NINETEENTH FLOOR, CLEVELAND, OH, 44115-2191, US

(21) Appl. No.: 11/325,477

(22) Filed: Jan. 4, 2006

(51) Int. Cl. H03F 3/08

(52) U.S. Cl. 250/214 A

(57) ABSTRACT

A TIA protection circuit comprises a TIA bias supply V_{TIA} for applying a bias voltage to the TIA, an APD bias supply V_{APD} for applying a bias voltage to an APD connected to an input of the TIA, and TIA protection means for reducing the bias voltage applied to the APD to a safe level when the power supplied to the TIA is removed so as to protect the input of the TIA from the application of an excessive voltage. This provides fast protection against high voltages to the input stage of a CMOS-based TIA that is simple and reliable in operation. Due to space limitations and power consumption constraints in small form factor pluggable modules, such as XFP and SFP modules, the circuit must be simple, small and require very low power. Several alternative protection schemes are possible, one using a circuit in parallel with the APD bias supply and one using circuit in series with the APD bias supply. The parallel protection scheme uses a fast switch in parallel with the APD bias supply so that, when the TIA bias voltage is turned off for any reason, the protection switch will connect the APD cathode (and TIA input) to ground (0V). In the serial protection scheme the protection switch is connected between the APD and APD bias supply so that, when the TIA bias voltage is turned off for any reason, the protection switch will isolate the APD cathode from the high voltage APD bias supply.

### BACKGROUND OF THE INVENTION

This invention relates to transimpedance amplifier (TIA) protection circuits and is concerned more particularly, but not exclusively, with the use of such TIA protection circuits in small form factor pluggable transceiver modules of the type known as SFP and XFP operating at very high data rates, for example at data rates of up to 10 Gbit/s or more.

As technology increases the speed of CMOS-based IC chips to multi-gigabit data rates, increasing use is being made of such CMOS-based IC chips, such as the M02014 TIA supplied by Mindspeed Technologies, in pluggable module products, such as pluggable transceiver modules of the type known as SFP and XFP. Although the M02014 TIA has the advantages of high performance and low power consumption as compared with other technologies (SiGe or InGaAs), it has its own shortcomings. One problem is that the M02014 TIA tends to be very open circuit when the power supply is switched off. The circuit topology that has been used in the M02014 TIA does not have a DC path to ground at the signal input node when the power supply to the TIA is off. This could cause serious problems in avalanche photodiode (APD) based applications. When the power supply to the M02014 TIA is off, and the bias supply to the APD is on, there is no current flow, and there can be a very large amount of voltage on the input gate of the TIA. This may cause serious damage to the TIA.

Traditionally this problem can be solved by power supply sequencing so that the power supply to the TIA is turned on before the APD bias and turned off after the APD bias. However in pluggable module applications such power sequencing cannot be always true. For example, if the XFP/SFP module is removed from the system board, the power supply to the TIA may drop faster than the APD bias because the equivalent load of the TIA is much lower than the equivalent load of the APD.

It is an object of the invention to provide a TIA protection circuit that operates reliably to prevent damage to the TIA when the power supply to the TIA is switched off.

### SUMMARY OF THE INVENTION

According to the present invention there is provided a TIA protection circuit comprising TIA biasing means for applying a bias voltage to the TIA, avalanche photodiode (APD) biasing means for applying a bias voltage to an APD connected to an input of the TIA, and TIA protection means for reducing the bias voltage applied to the APD to a safe level when the power supplied to the TIA is removed so as to protect the input of the TIA from the application of an excessive voltage.

The invention provides a hardware solution to the problem of providing fast protection against high voltages to the input stage of a CMOS-based TIA that is simple and reliable in operation. Due to space limitations and power consumption constraints in small form factor pluggable modules, such as XFP and SFP modules, the circuit must be simple, small and require very low power. Several alternative protection schemes are possible, one using a circuit in parallel with the APD biasing means and one using circuit in series with the APD biasing means. The parallel protection scheme uses a fast switch in parallel with the APD bias supply so that, when the TIA bias voltage is turned off for any reason, the protection switch will connect the APD cathode (and TIA input) to ground (0V). In the serial protection scheme the protection switch is connected between the APD and APD bias supply so that, when the TIA bias voltage is turned off for any reason, the protection switch will isolate the APD cathode from the high voltage APD bias supply.

In one embodiment of the invention isolating means is provided for isolating the APD from the APD biasing means when the power supplied to the TIA is removed.

In a development of the invention APD overload protection means is provided for reducing the voltage applied to the input of the TIA to a safe level when the input optical power to the APD is above an APD protection threshold value. In one embodiment a single switch is provided for both APD overload protection and TIA protection.

### BRIEF DESCRIPTION OF THE DRAWINGS

In order that the invention may be more fully understood, a number of embodiments of TIA protection circuit in accordance with the invention will now be described, by way of example, with reference to the accompanying drawings, in which:

FIG. 1 is a simplified block diagram of a first embodiment utilising a parallel protection scheme;

FIG. 2 is a simplified block diagram of a second embodiment utilising a serial protection scheme;

FIG. 3 is a simplified block diagram of a third embodiment with APD overload protection;

FIG. 4 is a simplified block diagram of a fourth embodiment utilising an alternative parallel protection scheme; and

FIG. 5 is a simplified block diagram of a typical pluggable module with which such protection circuits may be used.

### DETAILED DESCRIPTION OF THE DRAWINGS

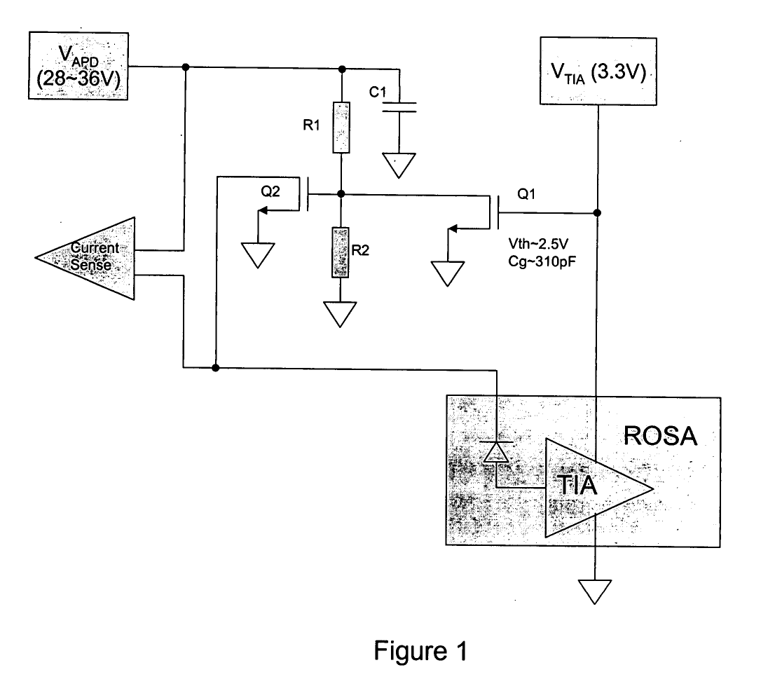

FIG. 1 is a block diagram of a protection circuit utilising a parallel protection scheme for a TIA and associated APD of a receiver optical sub-assembly (ROSA) of a 10 Gbit/s XFP transceiver module 1 for use in an optical fibre communication system. An APD bias supply V_{APD} of typically 28 to 36V is applied to the APD through a current sensing circuit CS, and a TIA bias supply V_{TIA} of typically 3.3V is applied to the TIA. The protection circuit uses two FET switches Q1 and Q2 biased by the bias supply V_{APD} and two resistors R1 and R2 and a capacitor C1 for TIA input protection. The drains of the two switches Q1 and Q2 are connected to ground, and the gate of the switch Q2 is connected to the source of the switch Q1, the resistor R1 being connected between the bias supply V_{APD} and the gate of the switch Q2, and the resistor R2 being connected between the gate of the switch Q2 and ground. The source of the switch Q2 is connected to the APD, and the gate of the switch Q1 is connected to the TIA. Under normal operating conditions the switch Q1 is on and the switch Q2 is off. If for some reason the TIA bias is switched off, the switch Q1 is opened and the switch Q2 is closed as long as the bias voltage V_{APD} is still applied to the switch Q2. In this case the switch Q2 will pull the voltage applied to the APD cathode down to ground, thereby protecting the input of the TIA.

Such a protection circuit is simple and works adequately provided that the threshold voltage Vₜₕ of the switch Q1 is between 2V and 3V, that the current mirror/APD bias supply can take a low impedance should the TIA bias come down, and that the time constant defined by the gate capacitance (typically 310 pF) of the switch Q1 and the resistors R1 and R2 is not too long. The resistor R1 constantly sees the full APD bias voltage (28˜36V) when all is well, so that the resistor value needs to be carefully selected. The voltage divider (R1 and R2) will protect the gate of the switch Q2 from being damaged in the TIA protection mode (so that the gate-source voltage V_{GS} needs to be kept less than 10V).

The transceiver module comprises a receiver optical sub-assembly (ROSA) for receiving a modulated optical signal transmitted along an optical fibre, and for supplying an electrical output signal representative of the data modulation of the optical signal, and a transmitter optical sub-assembly (TOSA) for receiving an electrical data signal and for modulating an optical output signal from a laser with the data signal to produce a modulated optical signal to be transmitted along an optical fibre to a remote receiver.

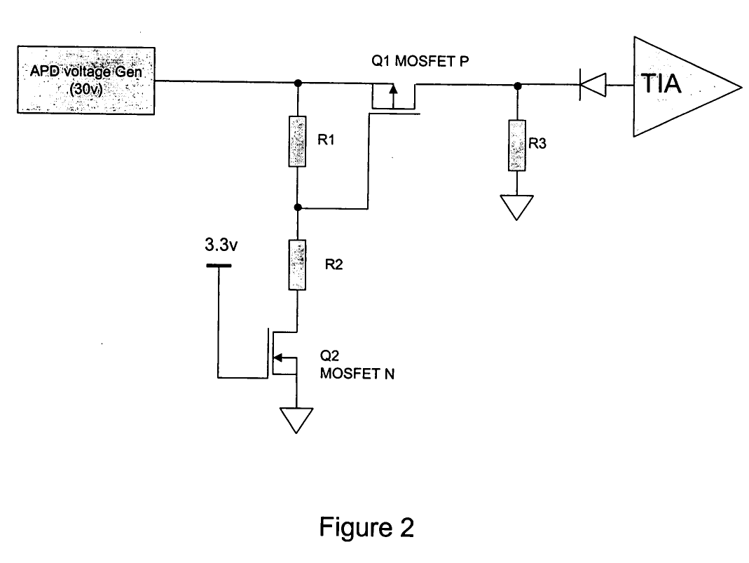

FIG. 2 is a block diagram of an alternative protection circuit for a TIA and associated APD of a receiver optical sub-assembly utilising a serial protection scheme (as opposed to the parallel protection scheme of FIG. 1). In this case the drain of the switch Q1 is connected to the bias supply V_{APD}, and the source of the switch Q1 is connected to the APD. The drain of the switch Q2 is connected to ground, and the source of the switch Q2 is connected to the bias supply V_{APD} by way of the resistors R1 and R2, the gate of the switch Q2 being connected to the TIA bias. The gate of the switch Q1 is connected to the centre point of the voltage divider R1/R2, and a resistor R3 is connected between the source of the switch Q1 and ground. Under normal operating conditions both of the switches Q1 and Q2 will be in low impedance states (closed). If for some reason the 3.3V supply to the TIA is switched off, then both of the switches Q1 and Q2 will be in high impedance states (open). This will isolate the APD cathode from the high voltage supply. The resistor R3 will pull the APD cathode to ground and thereby protect the TIA input from damage due to the application of excessive voltages.

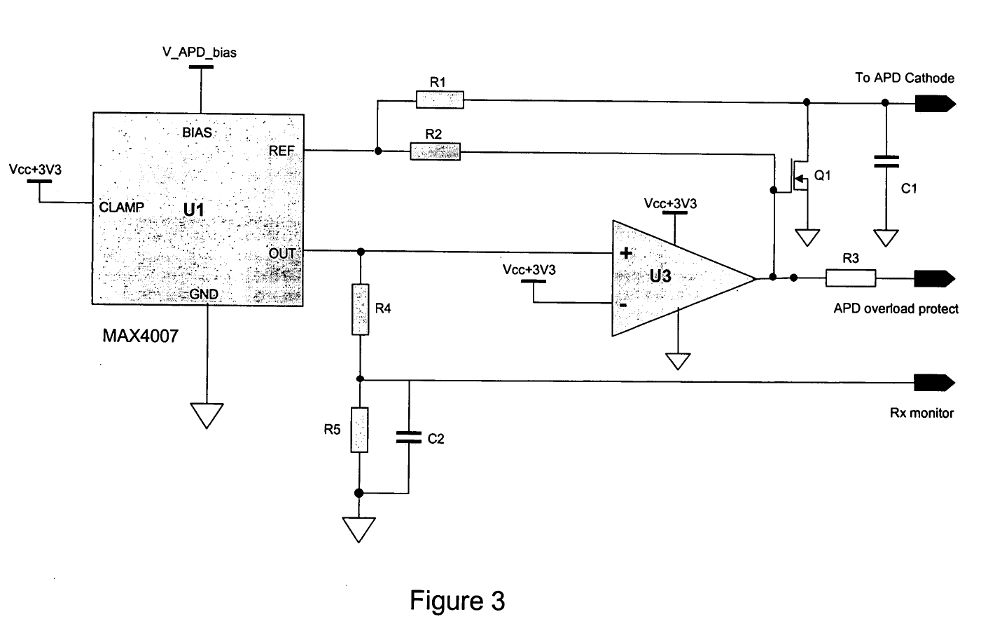

FIG. 3 is a block diagram of a third protection circuit for a TIA and associated APD of a receive optical sub-assembly utilising TIA input protection combined with APD overload protection. The circuit consists of a current monitor IC U1 connected to the APD bias supply V_{APD} and the TIA bias supply V_{TIA}, a fast comparator U3 with open drain output connected to the TIA bias supply V_{TIA}, a fast FET switch Q1 connected between the output of the comparator U3 and the APD cathode, a pull up resistor R2 for TIA protection, a serial resistor R1 for self-latching in the APD protection mode, and current sensing resistors R4 and R5 for APD current monitoring. The current monitor is connected to the centre point of the resistors R4 and R5 and to ground by a capacitor C2, and the APD cathode is connected to ground by a capacitor C1.

Under normal operating conditions (both V_{cc} and V_{bias} on) and when the input optical power is below the APD protection threshold (voltage at U3 pin3 is lower than V_{cc}), the output of the comparator U3 (pin1) is low and the protection switch Q1 is open. The APD bias voltage is applied to the APD cathode (not shown) by way of the resistor R3. In the APD overload condition, both V_{cc} and V_{bias} are on but the voltage at U3 pin 3 is above V_{cc}, so that the output of the comparator U3 (pin1) changes to high and the protection switch Q1 is closed. This will pull the APD cathode to a low safe voltage (close to 0V).

If the input optical power is below the threshold but the V_{cc} is off for some reason, the output of the comparator U3 (pin1) become open (the output of U3 is an open drain circuit). The resistor R3 will pull the gate of the switch Q1 to high and the switch Q1 will be closed. This will pull the voltage to the APD cathode to ground (0V) so that no voltage will be applied to the TIA input. The resistor R3 is also used to prevent any possibility of any ESD protection diode in the microprocessor I/O port pulling the gate of the switch Q1 to below the conducting threshold (1˜2.5V) if the supply voltage to the microprocessor is also off. If the input optical power is above the APD protection threshold and V_{cc} is off for some reason, the output of the comparator U3 (pin1) will still be open because no supply voltage is applied to the comparator, and the switch Q1 will be closed by the pull-up resistor R2. The APD cathode will be pulled down to a low safe voltage (close to 0V) and no voltage will be applied to the TIA input.

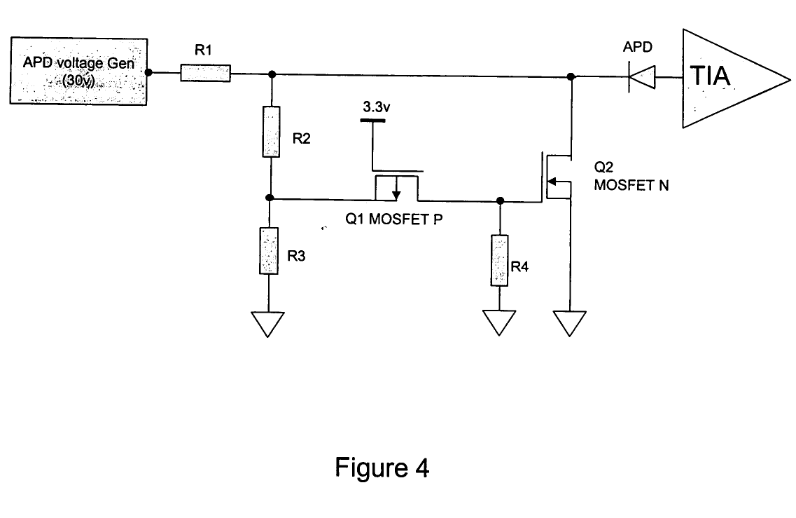

FIG. 4 is a block diagram of a fourth protection circuit for a TIA and associated APD of a receiver optical sub-assembly again utilising a parallel protection scheme. This circuit make use of an APD bias voltage monitor network comprising resistors R1, R2 and R3 similar to that already used but with the addition of two FET switches Q1 and Q2 and a further resistor R4. The ratio of the resistors R2/R3 is chosen so that, in the worst case (V_{bias}=35V), the monitor voltage is <3V so that normally the source to drain impedance of the switch Q1 is high (open) and the gate voltage of the switch Q2 is pulled low by the resistor R4 so that the impedance of the switch Q2 is also high (open). This represents the normal working condition in which the TIA protection switch Q2 is deactivated. If for some reason the TIA bias becomes low and the APD voltage stays high, the switch Q1 is biased by the resistors R1, R2 and R3 and the source to drain impedance of the switch Q1 becomes low (closed). This will pull up the gate of the switch Q2 to around 2˜3V, and the impedance of the switch Q2 becomes low (closed). In this case the APD cathode (and TIA input) will be pulled down to a low safe voltage (close to 0V).

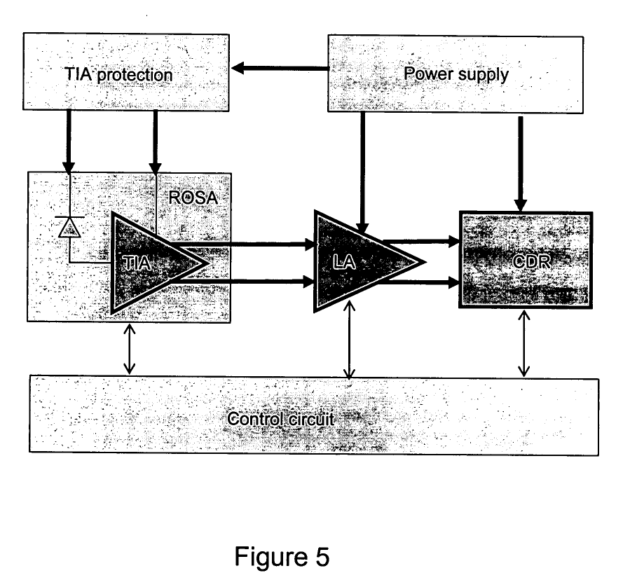

FIG. 5 is a simplified block diagram of a receiver circuit in a typical pluggable module with which the protection circuits described above may be used. The receiver circuit typically comprises a photodetector (PIN or APD) to convert an optical input signal into an electrical current signal, and a high gain transimpedance amplifier (TIA) to amplify the weak electrical current signal and to convert the current signal to a voltage signal. A limiting amplifier (LA) is normally used after the TIA to convert the analogue input signal into a digital signal which is supplied to a clock data recovery (CDR) circuit. The protection circuit described above will usually be positioned between the power supply circuit and the photodetector/TIA subassembly (ROSA) to provide safe and reliable operation. A microcontroller may also used to control and monitor all the other circuit blocks.

1. A transimpedance amplifier (TIA) protection circuit comprising TIA biasing means for applying a bias voltage to the TIA, avalanche photodiode (APD) biasing means for applying a bias voltage to an APD connected to an input of the TIA, and TIA protection means for reducing the bias voltage applied to the APD to a safe level when the power supplied to the TIA is removed so as to protect the input of the TIA from the application of an excessive voltage.

2. A circuit according to claim 1, wherein the TIA protection means comprises at least one switch.

3. A circuit according to claim 2, wherein the TIA protection means comprises at least one MOS field-effect transistor.

4. A circuit according to claim 1, wherein isolating means is provided for isolating the APD from the APD biasing means when the power supplied to the TIA is removed.

5. A circuit according to claim 1, wherein the TIA protection means comprises voltage detection means for detecting removal of the voltage applied to the TIA.

6. A circuit according to claim 1, wherein the TIA protection means comprises grounding means for grounding the APD when the power supplied to the TIA is removed.

7. A circuit according to claim 6, wherein the grounding means is disposed in parallel with the APD biasing means.

8. A circuit according to claim 6, wherein the grounding means is disposed in series with the APD biasing means.

9. A circuit according to claim 1, wherein APD overload protection means is provided for reducing the voltage applied to the input of the TIA to a safe level when the input optical power to the APD is above an APD protection threshold value.

10. A circuit according to claim 9, wherein a single switch is provided for both APD overload protection and TIA protection.

11. A circuit according to claim 9, wherein the APD overload protection means comprises a comparator for comparing the input optical power to an APD protection threshold value.

12. An optical assembly incorporating a TIA, an APD connected to an input of the TIA, and a transimpedance amplifier (TIA) protection circuit comprising TIA biasing means for applying a bias voltage to the TIA, avalanche photodiode (APD) biasing means for applying a bias voltage to the APD, and TIA protection means for reducing the bias voltage applied to the APD to a safe level when the power supplied to the TIA is removed so as to protect the input of the TIA from the application of an excessive voltage.
